(19) United States
(12) Patent Application Publication
(10) Pub. No.: US 2025/0038391 A1
(43) Pub. Date: Jan. 30, 2025

(54) NINETY DEGREE HYBRID COUPLER

(71) Applicant: STMicroelectronics International N.V., Geneva (CH)

(72) Inventor: Vincent KNOPIK, Crets En Belledonne (FR)

(73) Assignee: STMicroelectronics International N.V., Geneva (CH)

(21) Appl. No.: 18/785,654

(22) Filed: Jul. 26, 2024

(30) Foreign Application Priority Data
Jul. 27, 2023 (FR) 2308118

(51) Int. Cl. H01P 5/18

(52) U.S. Cl. CPC H01P 5/18

(57) ABSTRACT

Provided is a coupler including a first assembly of an input unit element, an intermediate unit element, and an output unit element. Each unit element includes a first coil and a second coil arranged in a cross having a general “H” shape. A first input terminal and a second input terminal of the intermediate unit element are coupled to a first output terminal and to a second output terminal of the input unit element, a first output terminal and a second output terminal of the intermediate unit element are coupled to a first input terminal and to a second input terminal of the output unit element, and the input unit element is spatially positioned between the intermediate unit element and the output unit element.

### CROSS-REFERENCE TO RELATED APPLICATION(S)

This application claims the priority benefit of French patent application number FR2308118, filed on Jul. 27, 2023, entitled “Coupleur hybride à quatre-vingt-dix degrés,” which is hereby incorporated by reference.

### BACKGROUND

### Technical Field

The present disclosure generally concerns electronic circuits and devices adapted to using signals, and in particular radio frequency signals. The present disclosure relates to a hybrid coupler, and more particularly to a ninety-degree hybrid coupler.

### Description of the Related Art

Couplers are electronic devices used to couple a plurality of electronic signals, and for example signals used in the radio frequency field, that is, signals having frequencies between a few hertz and more than 300 kHz, for example between 3 kHz and 300 GHz.

It would be desirable to be able to improve, at least partly, certain aspects of couplers, and in particular of hybrid couplers.

### BRIEF SUMMARY

There exists a need for higher-performance couplers.

There exists a need for couplers having a lower bulk.

An embodiment overcomes all or part of the disadvantages of known couplers.

An embodiment provides a coupler having a lower bulk.

An embodiment provides a coupler having fewer signal losses.

An embodiment provides a coupler comprising a first assembly of an input unit element, of an intermediate unit element, and of an output unit element, each unit element comprising:
a first coil and a second coil arranged in a cross having a general “H” shape;
a first input terminal corresponding to an input node of the first coil;
a second input terminal corresponding to an output node of the second coil;
a first output terminal corresponding to an output node of the first coil; and
a second output terminal corresponding to an input node of the second coil; wherein:
the first input terminal of the intermediate unit element is coupled to the first output terminal of the input unit element;
the second input terminal of the intermediate unit element is coupled to the second output terminal of the input unit element;
the first output terminal of the intermediate unit element is coupled to the first input terminal of the output unit element; and
the second output terminal of the intermediate unit element is coupled to the second input terminal of the output unit element, and wherein the input unit element is spatially positioned between the intermediate unit element and the output unit element.

According to an embodiment, the first input terminal of the input unit element is a first input of said first assembly, and the second input terminal of the input unit element is a second input of said first assembly.

According to an embodiment, the first output terminal of the output unit element is a first output of said first assembly, and the second output terminal of the output unit element is a second output of said first assembly.

According to an embodiment, the first input of said assembly is configured to receive a first signal, and the second input of said assembly is configured to receive a second signal equal to the first signal, phase-shifted.

According to an embodiment, the second signal is the first signal phase-shifted by ninety degrees.

According to an embodiment, the second signal is the first signal phase-shifted by one hundred and eighty degrees.

According to an embodiment, the coupler comprises at least one second assembly identical to the first assembly, wherein the first output of said first assembly is coupled to a first input of said second assembly, and the second output of said first assembly is coupled to a second input of said second assembly.

According to an embodiment, said unit elements all have the same dimensions.

According to an embodiment, said unit elements have different dimensions.

According to an embodiment, said unit elements are all placed in a same plane.

According to an embodiment, said unit elements are all placed in different planes.

According to an embodiment, said unit elements are placed in a stepped arrangement.

According to an embodiment, the first and second coils of said unit elements are windings having a generally rectangular shape.

According to an embodiment, the first and second coils of said unit elements are windings having a generally zigzag shape.

According to an embodiment, the coupler is a reversible coupler.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an electrical symbol and an equivalent electric diagram of an embodiment of a hybrid coupler;

FIG. 2 shows in top view a unit element forming a coupler according to the embodiment of FIG. 1;

FIG. 3 schematically shows an example of assembly of unit elements of FIG. 2;

FIG. 4 schematically shows an embodiment of an assembly of elements of FIG. 2 forming the coupler of FIG. 1;

FIG. 5 schematically shows another embodiment using two assemblies of FIG. 2 to form the coupler of FIG. 1;

FIG. 6 shows a top view of a practical example of the forming of the embodiment of FIG. 5; and

FIG. 7 shows a top view of another practical example of the forming of the embodiment of FIG. 5.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings.

Unless specified otherwise, the expressions “about,” “approximately,” “substantially”, and “in the order of” signify plus or minus 10%, preferably of plus or minus 5%.

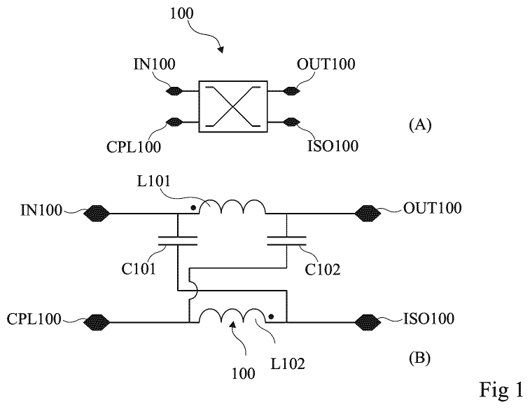

FIG. 1 shows diagrams (A) and (B) of a coupler 100 according to an embodiment. Diagram (A) shows the electrical symbol of coupler 100, and diagram (B) shows an equivalent electric diagram of coupler 100.

According to an embodiment, coupler 100 is a hybrid coupler. According to a preferred example, coupler 100 is a ninety-degree hybrid coupler. For this purpose, coupler 100 comprises:
a first input IN100 adapted to receiving a first signal;
a second input CPL100 adapted to receiving a second signal;
a first output OUT100 adapted to delivering a third signal; and
a second output ISO100 adapted to delivering a fourth signal.

According to an embodiment, the second signal is equal to the first signal, phase-shifted. According to the preferred example, the second signal is equal to the first signal phase-shifted by ninety degrees. According to another example within the abilities of those skilled in the art, the second signal is equal to the first signal phase-shifted by one hundred and eighty degrees.

When coupler 100 is a ninety-degree hybrid coupler, the third signal, delivered by output OUT100, corresponds to the sum of the signals received at the input, and the fourth signal is a zero signal.

According to an embodiment, coupler 100 is reversible, and by inverting the inputs and outputs may be a signal splitter circuit.

Coupler 100 comprises two coils L101 and L102 and two capacitors C101 and C102.

In FIG. 1, the input terminal of a coil is represented by a phase point, and the output terminal is left with no phase point. This means that the current flowing through the coil flows therethrough from the input terminal to the output terminal.

According to an embodiment, an input node of coil L101 is coupled, preferably connected, to input IN100 of coupler 100, and an output node of coil L101 is coupled, preferably connected, to output OUT100 of coupler 100. An input node of coil L102 is coupled, preferably connected, to output ISO100 of coupler 100, and an output node of coil L102 is coupled, preferably connected, to output OUT100 of coupler 100.

According to an embodiment, a first node of capacitor C101 is coupled, preferably connected, to input IN100 of coupler 100, and a second node of capacitor C101 is coupled, preferably connected, to output ISO100 of coupler 100. According to an embodiment, a first node of capacitor C102 is coupled, preferably connected, to input CPL100 of coupler 100, and a second node of capacitor C102 is coupled, preferably connected, to output OUT100 of coupler 100.

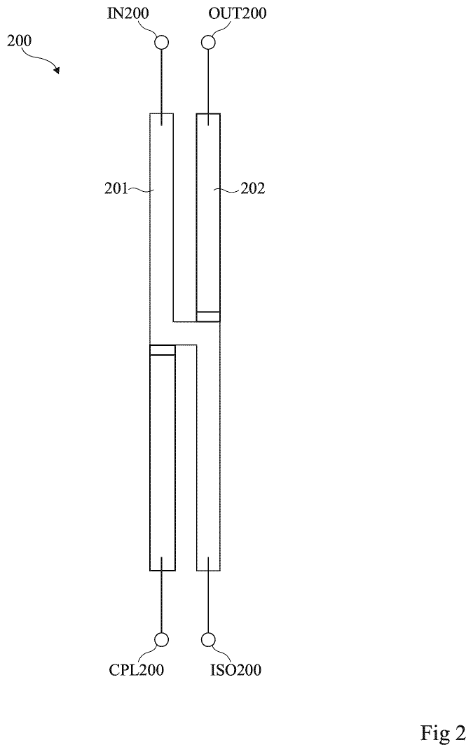

A physical implementation of coupler 100 is described in relation with FIG. 2, and assemblies of these implementations forming a coupler are described in relation with FIGS. 4 to 7.

FIG. 2 is a top view of a physical implementation of the coupler 100 described in relation with FIG. 1. More specifically, FIG. 2 is a top view of a unit element 100 enabling to form coupler 100.

Unit element 100 comprises two coils 201 and 202 arranged in the form of a cross or of an “x”. More particularly, first coil 201 forms a first branch of the cross, or of the “x”, and second coil 202 forms a second branch of the cross, or of the “x”.

More particularly, the two coils 201 are arranged in the form of a cross having a general “H” shape. In other words, all the branches of the cross formed by coils 201 and 202 follow a same direction, and are thus parallel to one another. Thus, there is here called a cross having a generally “H” shape the shape taken by the coils 201 and 202 shown in FIG. 2.

Unit element 200 comprises two input terminals and two output terminals similar to the inputs and outputs of coupler 100. More particularly, unit element 200 comprises:
a first input terminal IN200 corresponding to an input node of coil 201;
a second input terminal CPL200 corresponding to an output node of coil 202;
a first output terminal OUT200 corresponding to an output node of coil 202; and
a second output terminal ISO200 corresponding to an input node of coil 202.

The capacitors of the coupler are de facto formed between the branches of the cross of coils 201 and 202. More particularly, the capacitors represent the intrinsic capacitances of the branches of the cross formed by the coils. According to a variant, capacitors may be added to the structure disclosed in FIG. 2.

The dimensions of unit element 200 enable to define the electrical characteristics of the coupler, such as the inductances of coils 201 and 202 and the capacitances of the capacitors. The dimensions of unit element 200 should thus be adapted to adjust the functionality of the coupler that it forms.

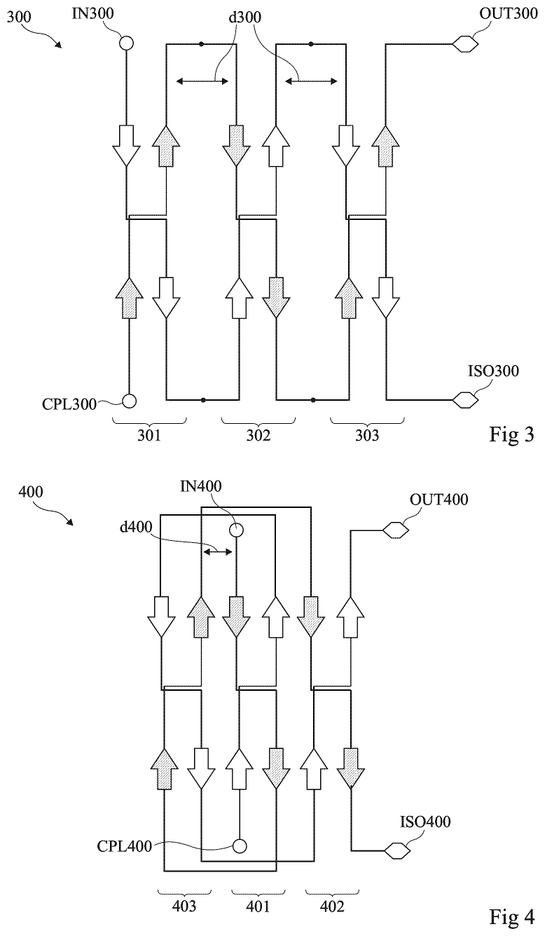

A unit element 200 enables to implement a coupler of the type of coupler 100, but it is also possible to assemble a plurality of unit elements 200 to obtain a coupler of the type of coupler 100. An advantage of assembling a plurality of unit elements 200 to form it is that this enables to limit the bulk of a coupler 100 while enabling to give it different shapes. A first example of an assembly of unit elements 200 is described in relation with FIG. 3, but this assembly has disadvantages. An embodiment of an assembly overcoming these disadvantages is described in relation with FIG. 4.

FIG. 3 very schematically shows an example of an assembly 300 of unit elements of the type of the unit element 200 described in relation with FIG. 2.

In FIG. 3, each unit element is very schematically represented by their general shape represented in the form of a wire. Further, the currents of the signals applied to the input terminals of the unit elements, and their directions, are represented by arrows. Since two different signals are applied to the input terminals of the unit elements, two arrow “colors” are used to differentiate them.

Assembly 300 forms a coupler of the type of the coupler 100 described in relation to FIG. 1, and thus comprises two inputs IN300 and CPL300, and two outputs OUT300 and ISO300.

Assembly 300 comprises three unit elements, among which:
an input unit element 301;
an intermediate unit element 302; and
an output unit element 303.

Input unit element 301 is characterized in that its input terminals are coupled to the inputs of the assembly. More particularly, a first input terminal of element 301 is coupled, preferably connected, to input IN300 of the assembly, and a second input terminal of element 301 is coupled, preferably connected, to input CPL300 of the assembly.

Output unit element 303 is characterized in that its output terminals are coupled to the outputs of assembly 300. More particularly, a first output terminal of element 303 is coupled, preferably connected, to output OUT300 of assembly 300, and a second output terminal of element 303 is coupled, preferably connected, to output ISO300 of assembly 300.

Intermediate unit element 302 is characterized in that it is positioned between the input and output unit elements 301 and 303. More particularly, a first input terminal of element 302 is coupled, preferably connected, to a first output terminal of element 301, and a second input terminal of element 302 is coupled, preferably connected, to a second output terminal of element 301. A first output terminal of element 302 is coupled, preferably connected, to a first input terminal of element 303, and a second output terminal of element 302 is coupled, preferably connected, to a second input terminal of element 303.

A disadvantage of assembly 300 is that the positioning of the unit elements presents exhibits constraints that may increase the area occupied by assembly 300. In particular, parasitic coupling phenomena may appear at the connections between unit elements. Indeed, as described hereabove, the unit elements are formed by coils, and, at the connections between unit elements, two coils side by side are arranged in parallel and are crossed by the same current but in different directions, as shown in FIG. 3. To avoid these parasitic coupling phenomena, the unit elements must be spaced apart by a distance d300, which increases the bulk.

FIG. 4 shows, very schematically, an embodiment of an assembly 400 of unit elements of the type of the unit element 200 described in relation with FIG. 2.

Assembly 400 forms a coupler of the type of the coupler 100 described in relation with FIG. 1, and thus comprises two inputs IN400 and CPL400, and two outputs OUT400 and ISO400.

Assembly 400 comprises three unit elements, including:
an input unit element 401;
an intermediate unit element 402; and
an output unit element 403.

Input unit element 401 is characterized in that its input terminals are coupled to the inputs of the assembly. More particularly, a first input terminal of element 401 is coupled, preferably connected, to input IN400 of assembly 400, and a second input terminal of element 401 is coupled, preferably connected, to input CPL400 of assembly 400.

Output unit element 403 is characterized in that its output terminals are coupled to the outputs of assembly 400. More particularly, a first output terminal of element 403 is coupled, preferably connected, to output OUT400 of assembly 400, and a second output terminal of element 403 is coupled, preferably connected, to output ISO400 of assembly 400.

Intermediate unit element 402 is characterized in that it is coupled to the input and output unit elements 401 and 403. More particularly, a first input terminal of element 402 is coupled, preferably connected, to a first output terminal of element 401, and a second input terminal of element 402 is coupled, preferably connected, to a second output terminal of element 401. A first output terminal of element 402 is coupled, preferably connected, to a first input terminal of element 403, and a second output terminal of element 402 is coupled, preferably connected, to a second input terminal of element 403.

According to an embodiment, input unit element 401 is spatially arranged between intermediate unit element 402 and output unit element 403. In other words, input unit element 401 is physically positioned between intermediate unit element 402 and output unit element 403, without modifying the connections between unit elements.

This embodiment has several advantages.

A first advantage is that it enables to increase the distance between consecutive unit elements, while optimizing the space lost between unit elements. Only a minimum distance d400 is imposed between the input unit element and the intermediate unit element to avoid a less intense parasitic coupling phenomenon than those present in the assembly 300 of FIG. 3.

A second advantage is that it enables to avoid having coils side by side crossed by the same current, and thus to avoid the appearing of parasitic coupling phenomena.

A third advantage is that it enables to have a new coupling between the two input signals, this coupling being visible in FIG. 4 between unit element 401 and unit element 403. Indeed, as shown in FIG. 4, two coils, each crossed by a different current, are placed side by side. Adding this coupling enables to decrease the losses of the coupler formed by assembly 400, and thus to improve its performance.

Further, it should also be noted that the unit elements 401, 402, and 403 schematically shown in FIG. 4 all have similar dimensions, but, as a variant, unit elements 401, 402, and 403 may have different dimensions and, in particular, different lengths of unit elements.

Further, in FIG. 4 and to simplify the understanding, unit elements 401, 402, and 403 are shown in a same plane. However, those skilled in the art will be capable of arranging unit elements 401, 402, and 403 in a three-dimensional model. Thus, it is possible to arrange the unit elements one above the other in a stepped arrangement.

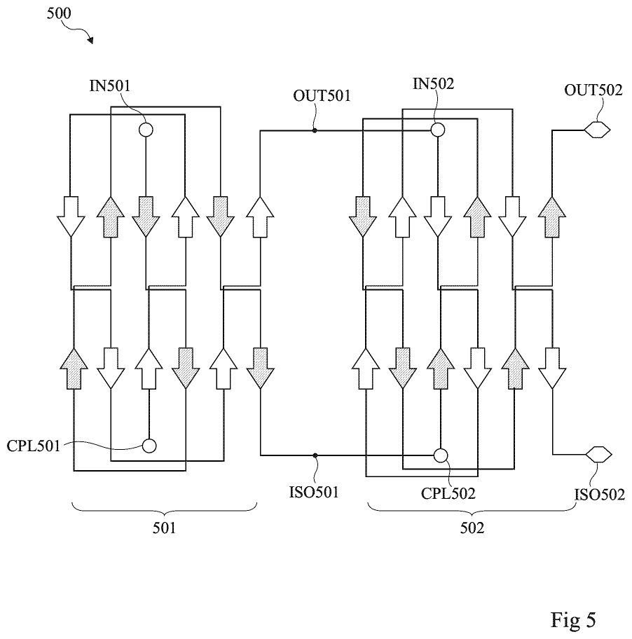

FIG. 5 shows, very schematically, a coupler 500 according to an embodiment.

Coupler 500 comprises two assemblies 501 and 502 of the type of the assembly 400 described in relation with FIG. 4.

Assembly 501 comprises:
a first input terminal IN501;
a second input terminal CPL501;
a first output terminal OUT501; and
a second output terminal ISO501.

Assembly 502 comprises:
a first input terminal IN502;
a second input terminal CPL502;
a first output terminal OUT502; and
a second output terminal ISO502.

To form coupler 500, assemblies 501 and 502 are connected “in series”. In other words, output terminal OUT501 of assembly 501 is coupled, preferably connected, to input terminal IN502 of assembly 502, and output terminal ISO501 of assembly 501 is coupled, preferably connected, to input terminal CPL502 of assembly 502.

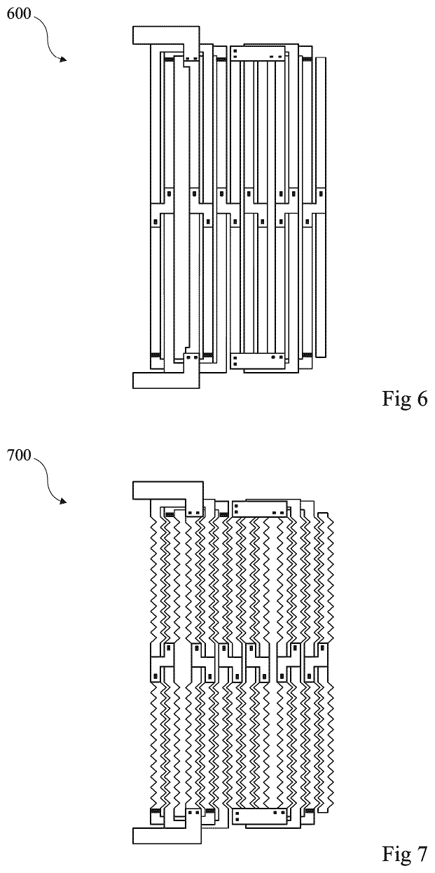

FIGS. 6 and 7 show top views of practical examples of implementation of the coupler 500 described in relation with FIG. 5. In particular, FIG. 6 shows a coupler 600, and FIG. 7 shows a coupler 700.

The difference between couplers 600 and 700 is that coupler 700 has zigzag-shaped coils, while coupler 600 has coils of generally rectangular shape. These coils have the advantage of improving the coupling performance of coupler 700. Indeed, when the unit elements of the assemblies of coupler 700 are folded in a zigzag pattern, advantageous couplings, that is, couplings desired by the coupler, are increased, and disadvantageous couplings, that is, couplings to be avoided, are decreased.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

Coupler (100; 400; 500; 600; 700) may be summarized as including a first assembly (400; 501) of an input unit element (401), of an intermediate unit element (402), and of an output unit element (403), each unit element (200) including: a first coil (201, 202) and a second coil (202, 201) arranged in a cross having a general “H” shape; a first input terminal (IN200) corresponding to an input node of the first coil (201, 202); a second input terminal (CPL200) corresponding to an output node of the second coil (202, 201); a first output terminal (OUT200) corresponding to an output node of the first coil (201, 202); a second output terminal (ISO200) corresponding to an input node of the second coil (202, 201); wherein: the first input terminal of the intermediate unit element (402) is coupled to the first output terminal of the input unit element (401); the second input terminal of the intermediate unit element (402) is coupled to the second output terminal of the input unit element (401); the first output terminal of the intermediate unit element (402) is coupled to the first input terminal of the output unit element (403); and the second output terminal of the intermediate unit element (402) is coupled to the second input terminal of the output unit element (403), and wherein the input unit element (401) is spatially positioned between the intermediate unit element (402) and the output unit element (403).

The first input terminal of the unit input element (401) may be a first input of said first assembly (400; 501), and the second input terminal of the unit input element (401) may be a second input of said first assembly (400; 501).

The first output terminal of the output unit (403) may be a first output of said first assembly (400; 501), and the second output terminal of the output unit element (403) may be a second output of said first assembly (400; 501).

The first input of said assembly may be configured to receive a first signal, and the second input of said assembly may be configured to receive a second signal equal to the first signal, phase-shifted.

The second signal may be the first signal phase-shifted by ninety degrees.

The second signal may be the first signal phase-shifted by one hundred and eighty degrees.

The first input terminal of the unit input element (401) may be a first input of said first assembly (400; 501), and the second input terminal of the unit input element (401) may be a second input of said first assembly (400; 501), and wherein said coupler may include at least one second assembly (400; 502) identical to the first assembly (400; 501), wherein the first output of said first assembly (400; 501) may be coupled to a first input of said second assembly (400; 502), and the second output of said first assembly (400; 501) may be coupled to a second input of said second assembly (400; 502).

Said unit elements may all have the same dimensions.

Said unit elements may have different dimensions.

Said unit elements may be all placed in a same plane.

Said unit elements may be all placed in different planes.

Said unit elements may be placed in a stepped arrangement.

The first and second coils of said unit elements may be windings having a generally rectangular shape.

The first and second coils of said unit elements may be windings having a generally zigzag shape.

Coupler may be a reversible coupler.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A coupler comprising:
a first assembly having:
an input unit element,
an intermediate unit element, and
an output unit element, where each unit element includes:
a first coil and a second coil arranged to generally have an “H” shape;
a first input terminal corresponding to an input node of the first coil;
a second input terminal corresponding to an output node of the second coil;
a first output terminal corresponding to an output node of the first coil; and
a second output terminal corresponding to an input node of the second coil;
wherein:
the first input terminal of the intermediate unit element is coupled to the first output terminal of the input unit element,
the second input terminal of the intermediate unit element is coupled to the second output terminal of the input unit element,
the first output terminal of the intermediate unit element is coupled to the first input terminal of the output unit element, and
the second output terminal of the intermediate unit element is coupled to the second input terminal of the output unit element, and
wherein the input unit element is spatially positioned between the intermediate unit element and the output unit element.

2. The coupler according to claim 1, wherein the first input terminal of the input unit element is a first input of the first assembly, and the second input terminal of the input unit element is a second input of the first assembly.

3. The coupler according to claim 1, wherein the first output terminal of the output unit element is a first output of the first assembly, and the second output terminal of the output unit element is a second output of the first assembly.

4. The coupler according to claim 2, wherein the first input of the first assembly is configured to receive a first signal, and the second input of the first assembly is configured to receive a second signal that is a phase-shifted version of the first signal.

5. The coupler according to claim 4, wherein the second signal is the first signal as phase-shifted by ninety degrees.

6. The coupler according to claim 4, wherein the second signal is the first signal as phase-shifted by one hundred and eighty degrees.

7. The coupler according to claim 3, wherein:
the first input terminal of the input unit element is a first input of the first assembly, and the second input terminal of the input unit element is a second input of the first assembly,
the coupler includes at least one second assembly identical to the first assembly,
the first output of the first assembly is coupled to a first input of the second assembly, and
the second output of the first assembly is coupled to a second input of the second assembly.

8. The coupler according to claim 1, wherein the unit elements all have the same dimensions.

9. The coupler according to claim 1, wherein the unit elements have different dimensions.

10. The coupler according to claim 1, wherein the unit elements are all placed in a same plane.

11. The coupler according to claim 1, wherein the unit elements are all placed in different planes.

12. The coupler according to claim 11, wherein the unit elements are placed in a stepped arrangement.

13. The coupler according to claim 1, wherein the first and second coils of the unit elements are windings having a generally rectangular shape.

14. The coupler according to claim 1, wherein the first and second coils of the unit elements are windings having a generally zigzag shape.

15. The coupler according to claim 1, wherein the coupler is a reversible coupler.

16. The coupler according to claim 1, wherein the first coil and the second coil each include:
a plurality of arms; and
a bridge between the plurality of arms.

17. The coupler according to claim 16, wherein the bridge is perpendicular to the plurality of arms, and the bridge centered relative to the plurality of arms, and the plurality of arms each have a length that is greater than a width of the bridge.

18. The coupler according to claim 1, comprising:
a patterned shield including a plurality of arms positioned in a proximity of the coupler.

19. The coupler according to claim 1, wherein the patterned shield is located at one or more levels below, above or around the coupler.
